(19) United States
(12) Patent Application Publication
(10) Pub. No.: US 2010/0182301 A1
(43) Pub. Date: Jul. 22, 2010

(54) Operational amplifier, semiconductor device, and display device

(75) Inventor: Tsukasa Yasuda, Siga (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/654,836

(22) Filed: Jan. 6, 2010

(30) Foreign Application Priority Data
Jan. 20, 2009 (JP) 2009-009669

(51) Int. Cl. G06F 3/038; H03F 3/45

(52) U.S. Cl. 345/211; 330/257

(57) ABSTRACT

An operational amplifier according to an exemplary aspect of the invention includes: a differential stage including a first differential transistor and a second differential transistor that serve as paired transistors; polarity switching units; and an offset adding unit that is connected to one or both of the paired transistors to change a size balance between the first differential transistor and the second differential transistor. The offset adding unit includes a first additional transistor that is connected in parallel with one or both of the paired transistors and receives the same input as one or both of the paired transistors connected, and a second additional transistor connected in series with the first additional transistor, turning on/off of the second additional transistor being controlled by a test signal. The operational amplifier according to an exemplary aspect of the invention enables determination of an offset cancel operation with higher accuracy.

### INCORPORATION BY REFERENCE

This application is based upon and claims the benefit of priority from Japanese patent application No. 2009-009669, filed on Jan. 20, 2009, the disclosure of which is incorporated herein in its entirety by reference.

### BACKGROUND

1. Field of the Invention

The present invention relates to an operational amplifier including a differential pair. The present invention also relates to a semiconductor device including the operational amplifier and to a display device incorporating the semiconductor device.

2. Description of Related Art

Liquid crystal displays (LCDs) characterized by their thinness, light weight, and low consumption of electric power are widely used as display units of mobile devices such as portable phones (mobile phones, cellular phones), personal digital assistances (PDAs), and notebook PCs. Recently, techniques for large-screen liquid crystal display devices and for liquid crystal display devices capable of displaying moving images have been improved. Such techniques have been applied to stationary large-screen display devices and large-screen liquid crystal televisions. As an example of the liquid crystal display devices, an active matrix drive type liquid crystal display device capable of high-definition display is used.

A typical structure of the active matrix drive type liquid crystal display device will be briefly described with reference to FIG. 5. FIG. 5 schematically shows an equivalent circuit for principal components connected to one pixel of a liquid crystal display unit.

The active matrix drive type liquid crystal display device has a structure in which a liquid crystal layer is sandwiched between a pair of substrates. The pair of substrates are generally composed of a semiconductor substrate having transparent pixel electrodes 81 and thin film transistors (hereinafter referred to as “TFT(s)”) 82 which are formed in a matrix form on a display area 80, and of an opposed substrate. A transparent opposed substrate electrode 83 is disposed on the entire surface of the opposed substrate. The liquid crystal has a capacitance, and a liquid crystal capacitance 84 is formed between each of the pixel electrodes 81 and the opposed substrate electrode 83. In order to supplement the capacitance of the liquid crystal, an auxiliary capacitance 85 is also provided in many cases.

Turning on/off of each TFT 82 is controlled by a scanning signal. When the TFT 82 is in ON state, a grayscale signal voltage that corresponds to a video data signal is applied to each of the pixel electrodes 81, and the transmissivity of the liquid crystal varies depending on a potential difference between each of the pixel electrodes 81 and the opposed substrate electrode 83. The liquid crystal capacitance 84 and the auxiliary capacitance 85 hold the potential difference for a predetermined period of time even after the TFT 82 is turned off, thereby enabling display of an image.

On the semiconductor substrate, data lines 92 for transmitting multi-level voltages (grayscale signal voltages) applied to each of the pixel electrodes 81, and scanning lines 91 for transmitting scanning signals are arranged in a matrix form. The scanning lines 91 and the data lines 92 provide a large capacitive load due to a capacitance generated at each intersection between each scanning line and each data line, and due to the liquid crystal capacitance 84 sandwiched between the pixel electrode and the opposed substrate electrode, or the like. In a frame area provided outside the display area 80, a gate driver 93 and a data driver 94, each of which is an LCD driver LSI (Large Scale Integration), are disposed.

The gate driver 93 supplies the scanning lines 91 with scanning signals. The data driver 94 supplies the grayscale signal voltage to each of the pixel electrodes 81 through the data lines 92. The gate driver 93 and the data driver 94 are supplied with a clock CLK, a control signal, a power supply voltage, and the like, which are necessary for each of the gate driver 93 and the data driver 94, by a display controller (not shown). The data driver 94 is supplied with video data from the display controller.

Data for one frame is overwritten every one frame period ( 1/60 seconds). In each scanning line, each of pixel rows (lines) is sequentially selected. The grayscale signal voltage is supplied from each data line within a selection period.

While the gate driver 93 should supply at least a binary scanning signal, the data driver 94 needs to drive the data lines 92 by multi-levels of grayscale signal voltages corresponding to the number of grayscales. For this reason, the data driver 94 includes a digital-analog conversion circuit (DAC) composed of a decoder for converting video data into a grayscale signal voltage, and an operational amplifier for amplifying and outputting the grayscale signal voltage to the data lines 92.

In recent years, along with the rapid increase in size and resolution of liquid crystal display devices including a TFT-type liquid crystal display module, a multi-grayscale display such as a 256-grayscale display has been used predominantly. For this reason, a voltage width per grayscale of the multi-grayscale voltage (i.e., a potential difference between adjacent grayscale voltages), which is generated by a multi-grayscale voltage generation circuit incorporated in the LCD driver LSI, has been reduced.

Meanwhile, in the operational amplifier which is an amplifier circuit incorporated in the driver LSI, an offset voltage is generated due to characteristic variations of active elements constituting the operational amplifier. This causes an error in the output voltage of the operational amplifier, and the output voltage deviates from a target value (regular grayscale voltage). This results in a problem of deterioration in display quality when each frame is displayed on a liquid crystal display panel (TFT-LCD). More specifically, there is a problem in that when outputs of adjacent amplifiers are selected to have the same grayscale (amplifier output voltage), for example, a black or white vertical stripe occurs due to brightness unevenness.

In view of this, Japanese Unexamined Patent Application Publication No. 11-249623 proposes the following method. That is, the direction of an offset voltage is alternately inverted and output every predetermined period from operational amplifiers respectively corresponding to video signal lines so that the brightness of a display device is alternately offset by the same voltage from a desired value, thereby making human eyes recognize as if there is no offset.

FIG. 6 is a circuit diagram showing an example of an operational amplifier 200 according to a related art, which includes a differential input pair used in an LCD driver LSI. FIG. 7 is a circuit diagram showing an operational amplifier 300 disclosed in Japanese Unexamined Patent Application Publication No. 11-249623. In a TFT-type liquid crystal display module, a voltage applied to a liquid crystal layer is generally converted into an alternating voltage every predetermined period. In other words, a voltage applied to a pixel electrode is caused to shift to a high-voltage side/low-voltage side every predetermined period, with a voltage applied to a so-called common electrode as a reference. An operational amplifier for low voltage which takes charge of the low-voltage side is herein described by way of example.

The operational amplifier 200 according to the related art shown in FIG. 6 includes a differential stage 210 with two differential transistors (first differential transistor and second differential transistor) which constitute a differential input pair. Specifically, the differential stage 210 includes a p-channel (p-type) MOS transistor P11 (hereinafter referred to as “first differential transistor P11”) and a p-type MOS transistor P12 (hereinafter referred to as “second differential transistor P12”).

The operational amplifier 200 also includes a current mirror circuit 230 which is located at an intermediate stage connected to the differential stage 210 and serves as an active load unit. The current mirror circuit 230 includes an n-channel (n-type) MOS transistor N11 (hereinafter referred to as “first intermediate transistor N11”) and an n-type MOS transistor N12 (hereinafter referred to as “second intermediate transistor N12”). The operational amplifier 200 also includes an NMOS transistor N13, a power supply 1, a power supply 2, a bias 1, and a bias 2.

The commonly connected sources of the first differential transistor P11 and the second differential transistor P12 are connected to the power supply 2. The gate of the first differential transistor P11 is connected to an inverting input terminal (−) and receives a (−) input signal. Likewise, the gate of the second differential transistor P12 is connected to a non-inverting input terminal (+) and receives a (+) input signal. The drain of the first differential transistor P11 is connected to the drain of the first intermediate transistor N11. Likewise, the drain of the second differential transistor P12 is connected to the drain of the second intermediate transistor N12. The sources of the first intermediate transistor N11 and the second intermediate transistor N12 are each connected to the power supply 1. The drain of the first intermediate transistor N11 is connected to the gate of the first intermediate transistor N11 and the gate of the second intermediate transistor N12.

A node “I” between the drain of the second differential transistor P12 and the drain of the second intermediate transistor N12 is connected to the gate of the NMOS transistor N13. The source of the NMOS transistor N13 is connected to the power supply 1, and the drain thereof is connected to an output terminal.

The operational amplifier 300 of FIG. 7, which is disclosed in Japanese Unexamined Patent Application Publication No. 11-249623, has a configuration in which switching transistors for switching between the (−) input signal and the (+) input signal are added to the differential amplifier circuit shown in FIG. 6. Specifically, switching transistors NA11 to NA14 and NB11 to NB14 are added. The gate electrodes of the switching transistors NA11 to NA14 are configured to receive a control signal A, and the gate electrodes of the switching transistors NB11 to NB14 are configured to receive a control signal B.

The switching transistors NA11 and NB11 act to connect the gate electrode (control terminal) of the first differential transistor P11 to the non-inverting input terminal (+) or the inverting input terminal (−). Likewise, the switching transistors NA12 and NB12 act to connect the gate electrode (control terminal) of the second differential transistor P12 to the non-inverting input terminal (+) or the inverting input terminal (−).

The switching transistors NA13 and NB13 act to connect the gate electrodes of the first intermediate transistor N11 and the second intermediate transistor N12, which constitute an active load circuit, to the drain electrode of the first differential transistor P11 or the drain electrode of the second differential transistor P12. The switching transistors NA14 and NB14 act to connect the gate electrode of the NMOS transistor N13 to the drain electrode of the first differential transistor P11 or the drain electrode of the second differential transistor P12.

FIG. 8 shows a circuit configuration of the operational amplifier 300 when the control signal A is at H level and the control signal B is at L level. FIG. 9 shows a circuit configuration of the operational amplifier 300 when the control signal A is at L level and the control signal B is at H level. FIGS. 8 and 9 also show circuit configurations in which the operational amplifiers shown in FIGS. 8 and 9 are expressed by using general operational amplifier symbols.

As illustrated in FIGS. 8 and 9, the operational amplifier 300 is configured to alternately switch the MOS transistor of the differential stage to which an input voltage (Vin) is applied and the MOS transistor of the differential stage to which an output voltage (Vout) is fed back. In the circuit configuration shown in FIG. 8, the output voltage (Vout) is obtained by adding an offset voltage (Voff) to the input voltage (Vin) as shown in the following Expression (1).

Vout=Vin+Voff (1)

On the other hand, in the circuit configuration shown in FIG. 9, the output voltage (Vout) is obtained by subtracting the offset voltage (Voff) from the input voltage (Vin) as shown in Expression (2).

Vout=Vin−Voff (2)

The phase of the operational amplifier is inverted every predetermined period by the control signal A and the control signal B, and voltages (Vin+Voff) and (Vin−Voff) are output to a data line (drain signal line) connected to the operational amplifier having the offset voltage Voff. Accordingly, in the corresponding pixels, a difference in brightness occurring due to the offset voltage (Voff) of the operational amplifier becomes less noticeable. Thus, a difference between the brightness of the pixels to which the output voltage is applied and the brightness corresponding to the grayscale voltage becomes less noticeable.

### SUMMARY

The present inventor has found a problem as described below. A so-called offset cancel function for making human eyes recognize an averaged voltage (i.e., recognize that the offset voltage is zero) is an indispensable technique for LCD driver LSIs. Thus, in tests for operational amplifiers having the offset cancel function, the logic operation of the output of amplifiers that perform an offset cancel operation is always checked. Specifically, a difference between output voltages generated before and after the offset cancel operation is switched (i.e., an offset voltage difference) is measured to check the operation of the offset cancel function.

In the case of a product having a characteristic in which the offset amount of an amplifier output is small by accident under measurement conditions at the time of checking the offset cancel operation, there occurs little difference between the output voltages generated before and after the offset cancel operation is switched. Meanwhile, in the case of a defective product incapable of performing the offset cancel function, the offset cancel operation is not carried out even when a signal for executing the offset cancel operation is input. Also in this case, there occurs little difference between the output voltages generated before and after the offset cancel operation is switched. Thus, it has been conventionally difficult to discriminate the defective product from the product having a small offset amount.

A first exemplary aspect of the present invention is an operational amplifier including: a differential stage including a first differential transistor and a second differential transistor, the first differential transistor and the second differential transistor serving as paired transistors; a first polarity switching unit that switches a connection destination of a control terminal of the first differential transistor between an inverting terminal and a non-inverting terminal; a second polarity switching unit that switches a connection destination of a control terminal of the second differential transistor between the inverting terminal and the non-inverting terminal; and an offset adding unit that is connected to one or both of the paired transistors to change a size balance between the first differential transistor and the second differential transistor. The offset adding unit includes a first additional transistor that is connected in parallel with one or both of the paired transistors and receives the same input as one or both of the paired transistors connected, and a second additional transistor connected in series with the first additional transistor, turning on/off of the second additional transistor being controlled by a test signal.

The operational amplifier according to the first exemplary aspect of the present invention includes the offset adding unit as a mode for changing the size balance between the paired transistors which constitute the differential pair of the operational amplifier. This makes it possible to check the logic operation of the offset cancel operation regardless of the actual offset voltage amount of the paired transistors. A discrimination between a defective product incapable of performing the offset cancel function and a product having a small offset amount of the amplifier output under measurement conditions at the time of checking the offset cancel operation, which has been conventionally difficult, can be achieved. Therefore, the offset cancel operation can be determined with higher accuracy.

According to an exemplary aspect of the present invention, there is achieved an advantageous effect that an operational amplifier capable of determining an offset cancel operation with higher accuracy can be provided.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a circuit diagram showing a circuit configuration of an operational amplifier according to a first exemplary embodiment of the present invention;

FIG. 2 is a circuit diagram showing a circuit configuration of the operational amplifier according to the first exemplary embodiment when a control signal A is at H level;

FIG. 3 is a circuit diagram showing a circuit configuration of the operational amplifier according the first exemplary embodiment when a control signal B is at H level;

FIG. 4 is a circuit diagram showing a circuit configuration of an operational amplifier according to a second exemplary embodiment of the present invention;

FIG. 5 is an explanatory diagram showing a configuration of a liquid crystal display device;

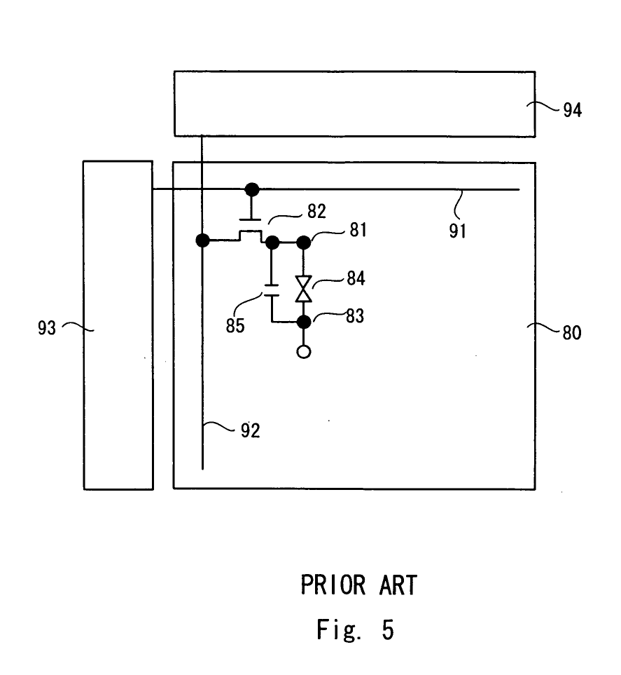

FIG. 6 is a circuit diagram showing an exemplary operational amplifier according to a prior art;

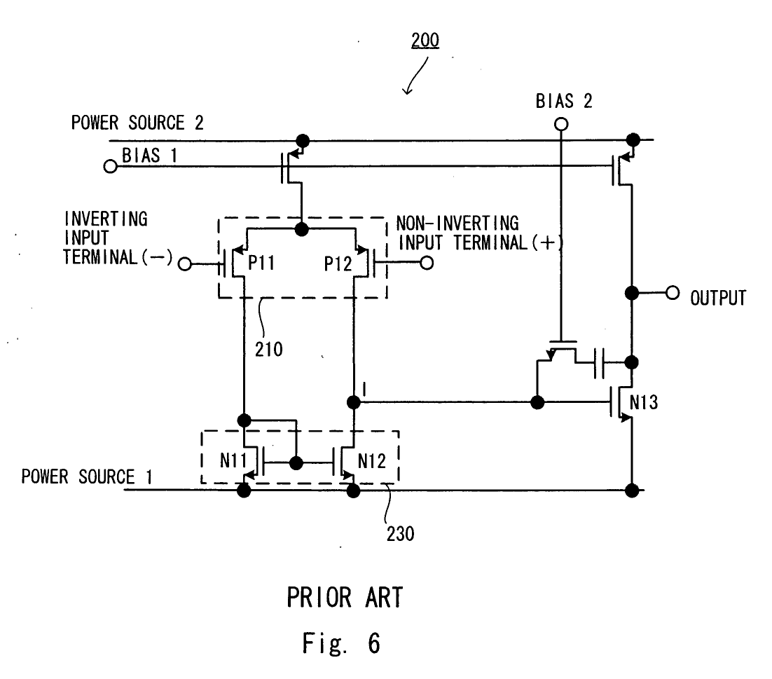

FIG. 7 is a circuit diagram showing a circuit configuration of an operational amplifier disclosed in Japanese Unexamined Patent Application Publication No. 11-249623;

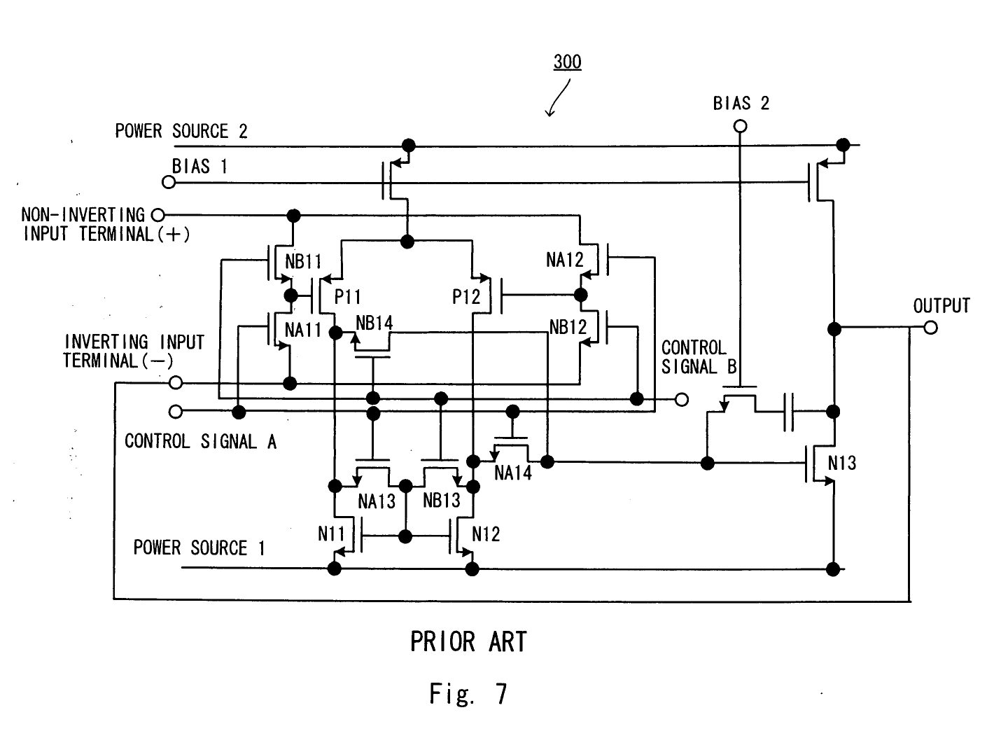

FIG. 8 is a circuit diagram showing a circuit configuration of the operational amplifier disclosed in Japanese Unexamined Patent Application Publication No. 11-249623 when the control signal A is at H level; and

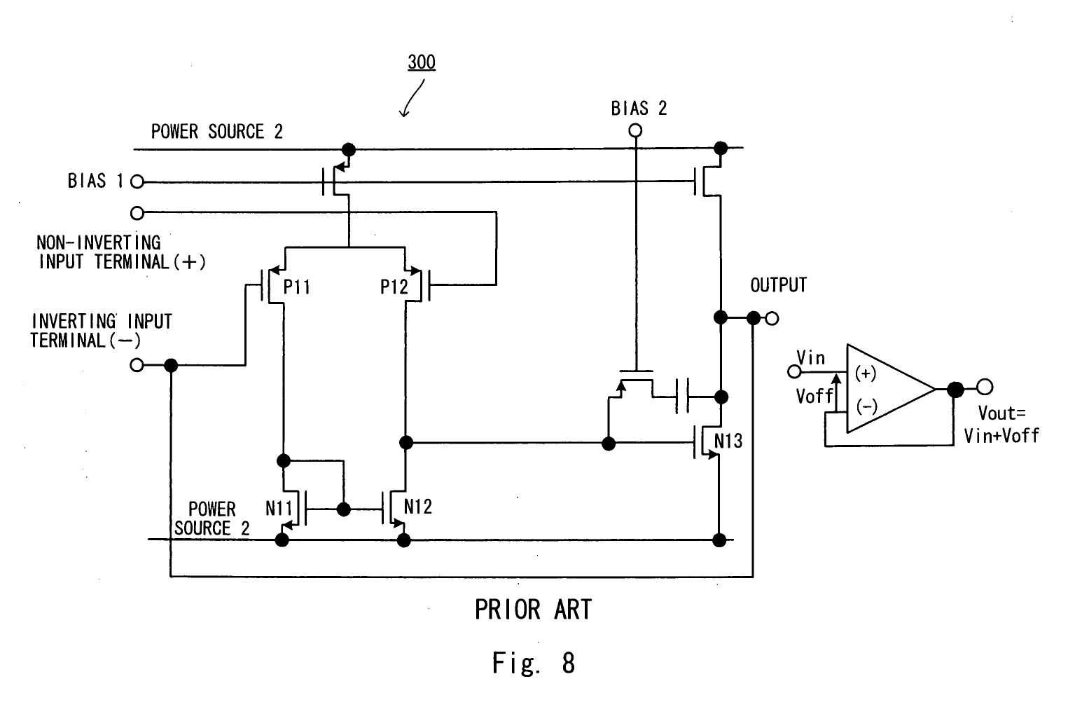

FIG. 9 is a circuit diagram showing a circuit configuration of the operational amplifier disclosed in Japanese Unexamined Patent Application Publication No. 11-249623 when the control signal B is at H level.

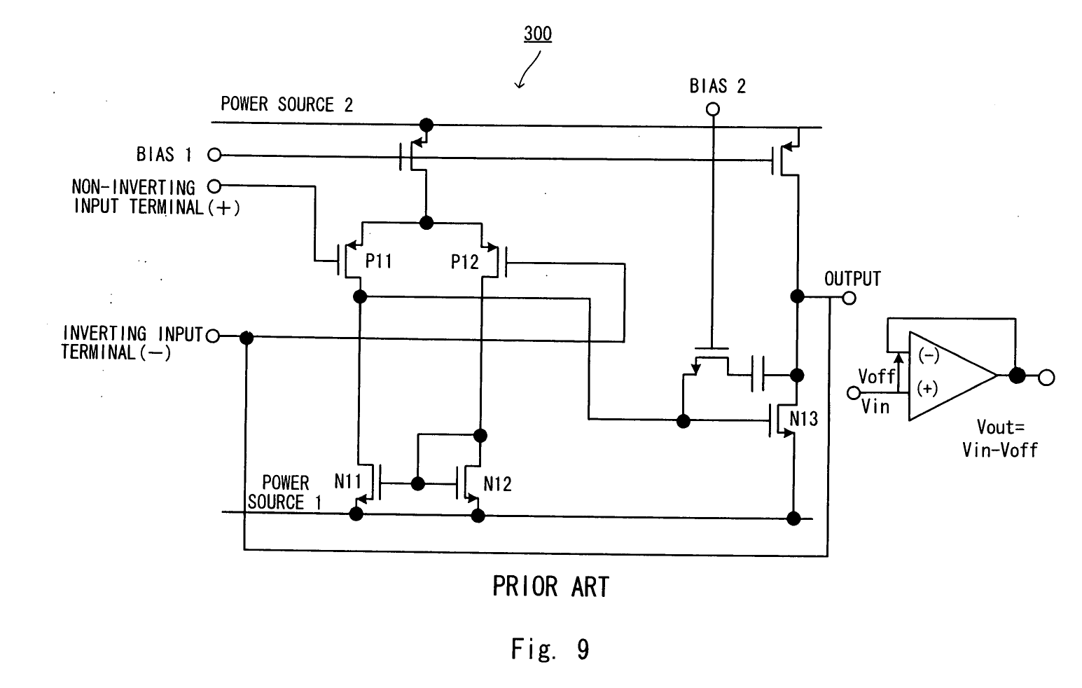

### DETAILED DESCRIPTION OF THE EXEMPLARY EMBODIMENTS

Exemplary embodiments of the present invention will be described below. Note that other embodiments may also belong to the scope of the present invention, as long as they meet the purpose of the present invention.

### First Exemplary Embodiment

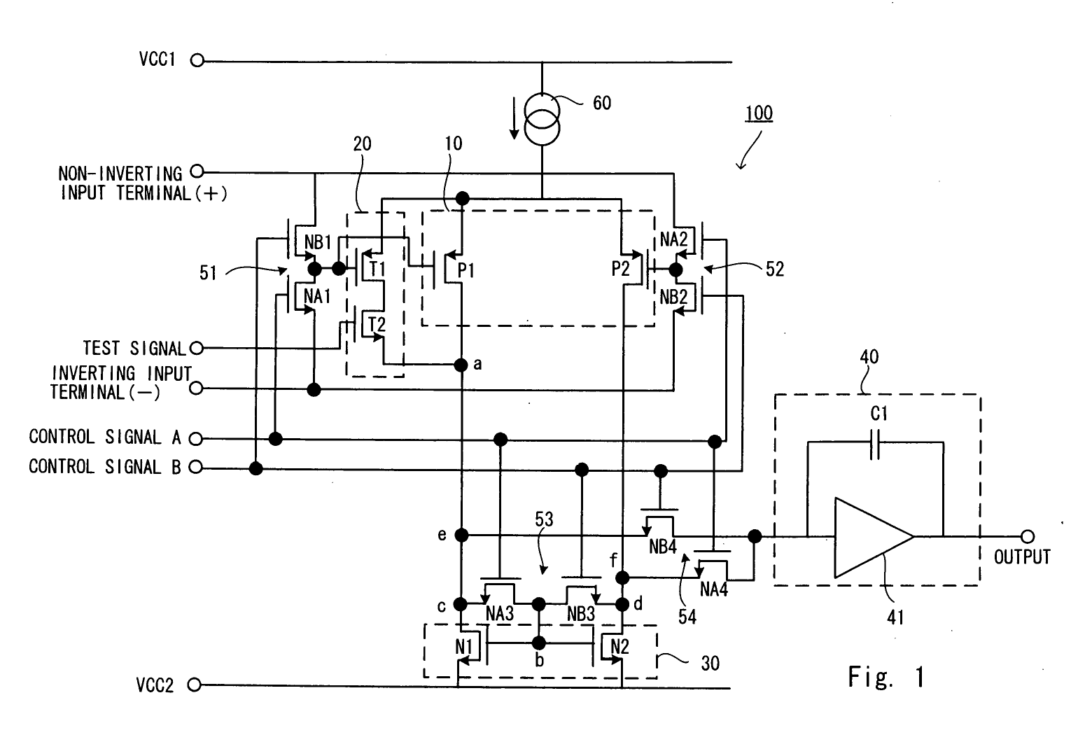

Reference is now made to FIG. 1 which is a circuit diagram illustrating an exemplary circuit configuration of an operational amplifier (amplifier circuit) according to a first exemplary embodiment of the present invention. An operational amplifier 100 has a function of cancelling an offset by changing an offset voltage. The operational amplifier 100 is suitably applicable as an operational amplifier of a semiconductor device such as a driver LSI incorporated in various display devices such as a liquid crystal display device and an EL display device.

The operational amplifier 100 includes an input differential stage 10 serving as a differential stage, an offset adding unit 20, a current mirror circuit 30, and an output unit 40. The operational amplifier 100 also includes a first polarity switching unit 51, a second polarity switching unit 52, a third polarity switching unit 53, a fourth polarity switching unit 54, a current source 60, and power supply voltages VCC1 and VCC2.

The input differential stage 10 includes a first differential transistor and a second differential transistor which serve as paired transistors and have a first conductivity type. In the first exemplary embodiment, a p-type MOS transistor serving as the first differential transistor (hereinafter referred to as “first differential transistor P1”) and a p-type MOS transistor serving as the second differential transistor (hereinafter referred to as “second differential transistor P2”) are arranged. The paired transistors are not limited to p-type transistors, and n-type transistors may also be used.

The offset adding unit 20 is connected to one or both of the paired transistors (first differential transistor P1 and second differential transistor P2), and acts to increase the offset amount of one or both of the differential transistors to be connected. The offset adding unit 20 according to the first exemplary embodiment is connected to the first differential transistor P1.

The offset adding unit 20 includes a first additional transistor T1 and a second additional transistor T2. The first additional transistor T1 is connected in parallel with the first differential transistor P1 and receives the same input as the first differential transistor P1. The second additional transistor T2 is connected in series with the first additional transistor T1, and turning on/off of the second additional transistor T2 is controlled by a test signal. In the first exemplary embodiment, the first additional transistor T1 is composed of a p-type MOS transistor, and the second additional transistor T2 is composed of an n-type MOS transistor.

The current mirror circuit 30 is located at an intermediate stage connected to the input differential stage 10 and serves as an active load unit. The current mirror circuit 30 includes a first intermediate transistor and a second intermediate transistor, each of which has a second conductivity type. In the first exemplary embodiment, an n-type MOS transistor serving as the first intermediate transistor (hereinafter referred to as “first intermediate transistor N1”) and an n-type MOS transistor serving as the second intermediate transistor (hereinafter referred to as “second intermediate transistor N2”) are arranged. The first intermediate transistor N1 and second intermediate transistor N2 of the current-mirror circuit configuration serve as active loads of the differential pair, and convert a received differential signal into a single end signal.

The output unit 40 is connected to a node between the input differential stage 10 and the current mirror circuit 30, and includes an output stage 41 and a phase compensating capacitor Cl. The phase compensating capacitor Cl is connected to both ends of the output stage 41.

The first polarity switching unit 51 includes switching transistors NA1 and NB1. Likewise, the second polarity switching unit 52 includes switching transistors NA2 and NB2, the third polarity switching unit 53 includes switching transistors NA3 and NB3, and the fourth polarity switching unit 54 includes switching transistors NA4 and NB4. The switching transistors NA1 to NA4 and NB1 to NB4 according to the first exemplary embodiment are composed of n-type MOS transistors.

The gate electrodes (control terminals) of the switching transistors NA1 to NA4 are configured to receive a control signal A, and the gate electrodes (control terminals) of the switching transistors NB1 to NB4 are configured to receive a control signal B. In other words, turning on/off of the switching transistors NA1 to NA4 is controlled by the control signal A, and turning on/off of the switching transistors NB1 to NB4 is controlled by the control signal B.

The sources of the first differential transistor P1, the second differential transistor P2, and the first additional transistor T1 are commonly connected. The commonly connected sources are connected to the current source 60 which is connected to the power supply potential VCC1. The drain of the first differential transistor P1 is connected to the drain of the first intermediate transistor N1. Likewise, the drain of the second differential transistor P2 is connected to the drain of the second intermediate transistor N2.

The gate electrode (control terminal) of the first differential transistor P1 and the gate of the first additional transistor T1 are each connected to the drain of the switching transistor NA1 and the source of the switching transistor NB1. Meanwhile, the gate electrode (control terminal) of the second differential transistor P2 is connected to the source of the switching transistor NA2 and the drain of the switching transistor NB2.

Each of the switching transistors NA1 and NB1 acts to connect the gate electrode of the first differential transistor P1 to a non-inverting input terminal (+) or an inverting input terminal (−). Likewise, each of the switching transistors NA2 and NB2 acts to connect the gate electrode of the second differential transistor P2 to the non-inverting input terminal (+) or the inverting input terminal (−).

The drain of the first additional transistor T1 is connected to the drain of the second additional transistor T2. The gate of the second additional transistor T2 is connected to a test signal terminal and receives the test signal. The source of the second additional transistor T2 is connected to a node “a” between the drain of the first differential transistor P1 and the drain of the first intermediate transistor N1.

The sources of the first intermediate transistor N1 and the second intermediate transistor N2 are each connected to the power supply potential VCC2. The gates of the first transistor N1 and the second intermediate transistor N2 are commonly connected to a node “b”, and the node “b” is connected to the drain of the switching transistor NA3 and the drain of the switching transistor NB3. The source of the switching transistor NA3 is connected to a node “c” between the drain of the first differential transistor P1 and the drain of the first intermediate transistor N1. Likewise, the source of the switching transistor NB3 is connected to a node “d” between the drain of the second differential transistor P2 and the drain of the intermediate transistor N2.

Each of the switching transistors NA3 and NB3 acts to switch a connection destination of each of the gate electrodes of the first intermediate transistor N1 and the second intermediate transistor N2, which constitute the current mirror circuit 30, between the drain electrode of the first differential transistor P1 and the drain electrode of the second differential transistor P2. In other words, the gate electrodes of the first intermediate transistor N1 and the second intermediate transistor N2, which constitute the current mirror circuit 30, are connected to the drain electrode of the first differential transistor P1 when the control signal A is at H level, and are connected to the drain electrode of the second differential transistor P2 when the control signal B is at H level.

Each of the switching transistors NA4 and NB4 acts to connect the output stage 41 to the drain electrode of the first differential transistor P1 or the drain electrode of the second differential transistor P2. Specifically, the source of the switching transistor NB4 is connected to a node “e” which is connected between the drain of the first differential transistor P1 and the drain of the first intermediate transistor N1 and which is connected between the node “a” and the node “c”. The drain of the switching transistor NB4 is connected to the output stage 41 of the output unit 40.

The source of the switching transistor NA4 is connected to a node “f” which is connected between the drain of the second differential transistor P2 and the drain of the second intermediate transistor N2 and which is located closer to the second differential transistor P2 than the node “d”. The drain of the switching transistor NB4 is connected to the output stage 41.

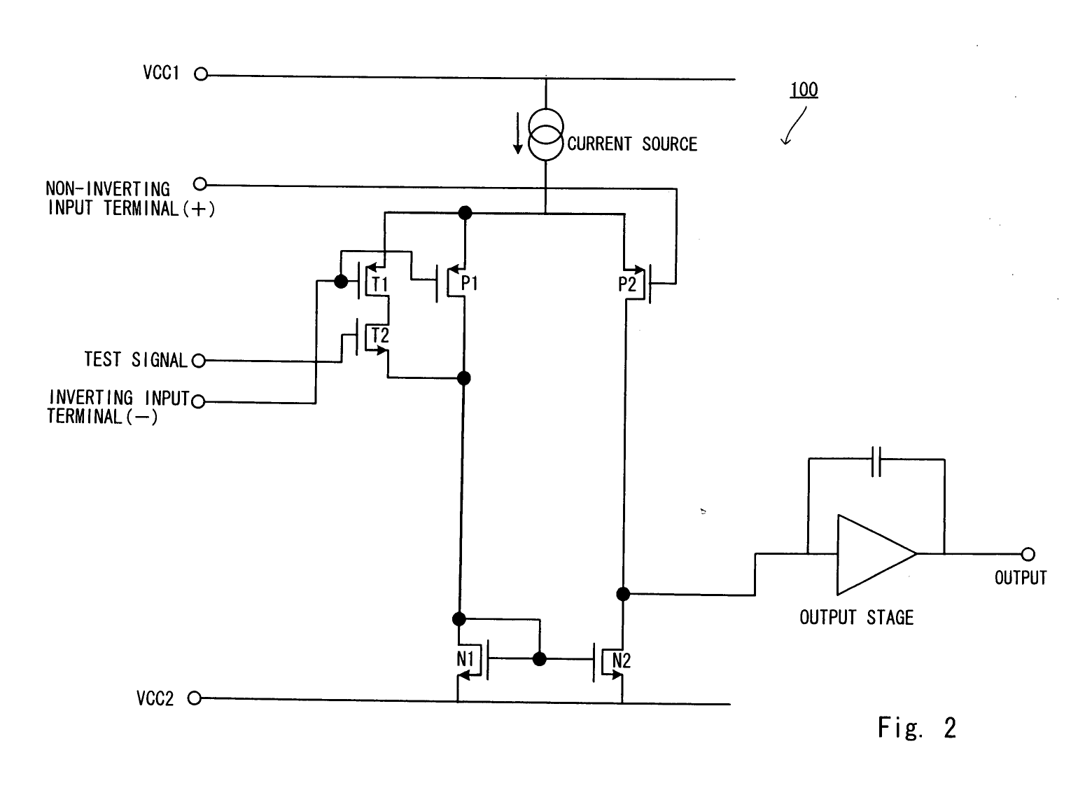

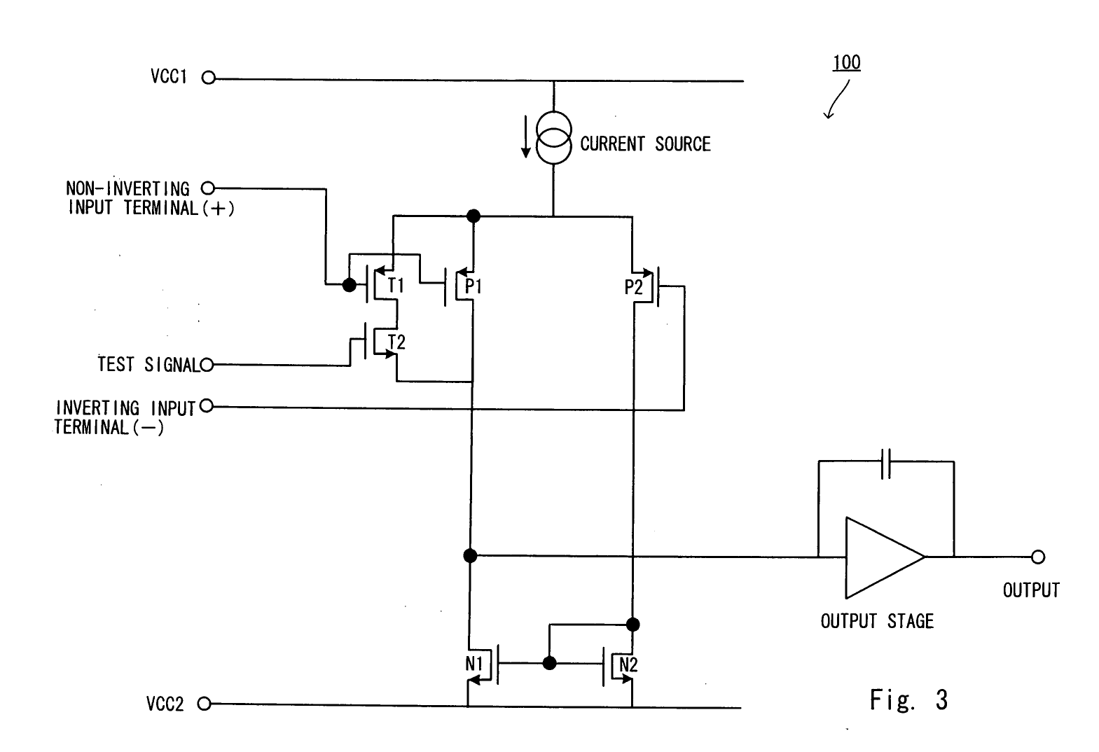

The operational amplifier 100 controls an offset cancel operation using two control signals of the control signal A and the control signal B which are signals having opposite phases. FIG. 2 shows a circuit configuration of the operational amplifier shown in FIG. 1 when the control signal A is at H level and the control signal B is at L level. FIG. 3 shows a circuit configuration of the operational amplifier shown in FIG. 1 when the control signal A is at L level and the control signal B is at H level. The operational amplifier 100 is configured to alternately switch the MOS transistor of the input differential stage to which an input voltage (Vin) is applied and the MOS transistor of the input differential stage to which an output voltage (Vout) is fed back. In this configuration, the phase of the operational amplifier is inverted every predetermined period by the control signal A and the control signal B. As a result, a difference in brightness occurring due to an offset voltage (Voff) of the operational amplifier having the offset voltage Voff becomes less noticeable. Thus, a difference between the brightness of the pixels to which the output voltage is applied and the brightness corresponding to the grayscale voltage becomes less noticeable.

The offset adding unit 20 is disposed so as to change a size balance between the paired transistors which constitute the input differential stage 10. In the first exemplary embodiment, the gate of the first additional transistor T1 receives the same input as the gate of the first differential transistor P1. As described above, the source of the first additional transistor T1 and the source of the first differential transistor P1 are commonly connected. The drain of the first additional transistor T1 is connected to the drain of the second additional transistor T2. The gate of the second additional transistor T2 is connected to the test terminal and receives the test signal as described above. The source of the second additional transistor T2 is connected to the node “a”.

When the test signal is at H level, the second additional transistor T2 constituting the offset adding unit 20 becomes active. Then, the effective size of the first differential transistor P1 is changed, which causes an imbalance between the paired transistors. As a result, the offset amount becomes extremely large, and a large offset voltage is generated in the amplifier output. This makes it possible to reliably perform logic verification for the offset cancel function by measuring the amplifier output voltage. In other words, the offset voltage is varied to a large extent by changing the test signal at the time of checking the offset cancel operation, thereby making it possible to reliably check the logic operation.

The operational amplifier according to the first exemplary embodiment has a mode in which the size balance between the paired transistors, which constitute the differential pair of the operational amplifier, is changed by the offset adding unit. This makes it possible to check the logic operation of the offset cancel operation regardless of the actual offset voltage amount of the paired transistors. A discrimination between a defective product incapable of performing the offset cancel function and a product having a small offset amount of the amplifier output under measurement conditions at the time of checking the offset cancel operation, which has been conventionally difficult, can be achieved. Therefore, the offset cancel operation can be determined with higher accuracy.

### Second Exemplary Embodiment

Next, a description is given of an operational amplifier according to another exemplary embodiment of the present invention, which is different from the first exemplary embodiment. In the drawings described below, components identical with those of the first exemplary embodiment are denoted by the same reference symbols, and the description thereof is omitted as appropriate.

The configuration of an operational amplifier 101 according to a second exemplary embodiment of the present invention is basically similar to that of the operational amplifier 100 according to the first exemplary embodiment except for the following points. That is, one transistor (first differential transistor P1) of the paired transistors constituting the input differential stage 10 is connected to the offset adding unit 20 in the operational amplifier 100 according to the first exemplary embodiment. Meanwhile, in the operational amplifier according to the second exemplary embodiment, both of the paired transistors (first differential transistor P1 and second differential transistor P2) constituting the input differential stage 10 are connected to the offset adding unit.

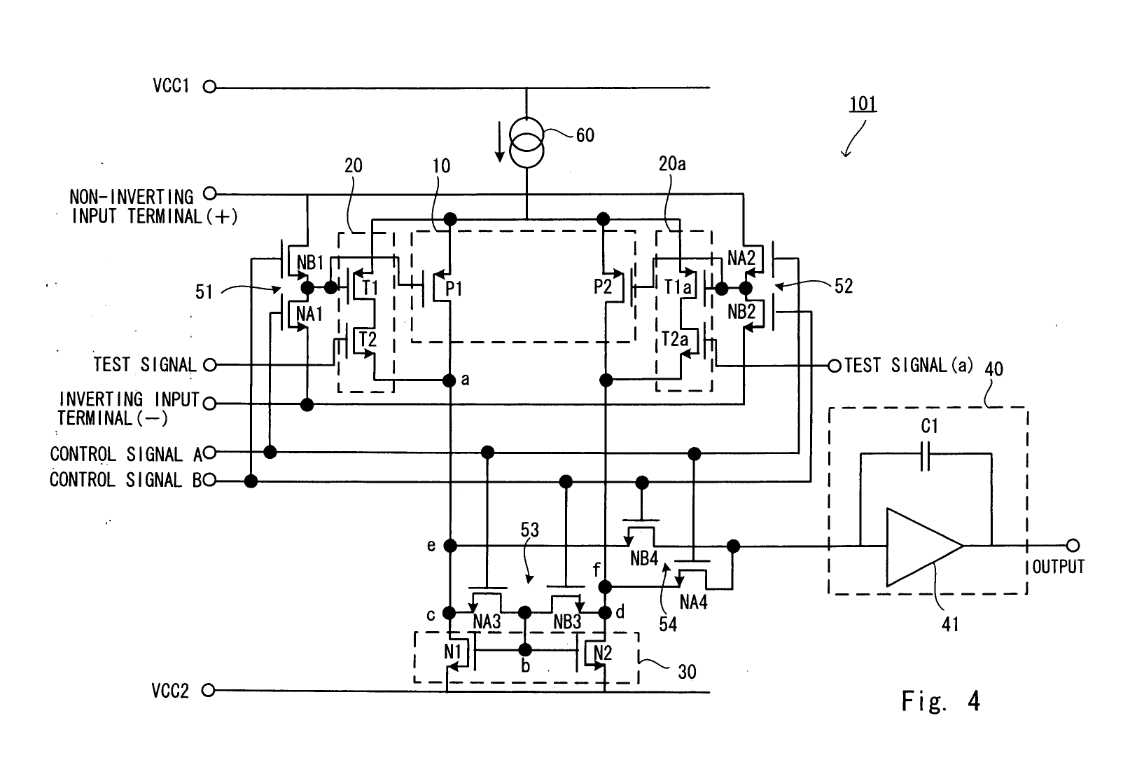

FIG. 4 is a circuit diagram showing the operational amplifier 101 according to the second exemplary embodiment. As shown in FIG. 4, in the second exemplary embodiment, there are provided two offset adding units: the offset adding unit 20 which is disposed in a similar manner as in the first exemplary embodiment and which is connected to the first differential transistor P1, and an offset adding unit 20a which is newly disposed in the second exemplary embodiment and which is connected to the second differential transistor P2.

The two offset adding units 20 and 20a have basically the same configuration. The offset adding unit 20a includes a first additional transistor T1a and a second additional transistor T2a. The first additional transistor T1a is connected in parallel with the second differential transistor P2, and receives the same input as the second differential transistor P2. The second additional transistor T2a is connected in series with the first additional transistor T1a, and turning on/off of the second additional transistor T2a is controlled by a test signal (a). The first additional transistor T1a constituting the offset adding unit 20a is composed of a p-type MOS transistor. The second additional transistor T2a constituting the offset adding unit 20a is composed of an n-type MOS transistor. The connection between the first additional transistor T1a and the second additional transistor T2a of the offset adding unit 20a connected to the second differential transistor P2 is similar to that of the offset adding unit 20 described in the first exemplary embodiment, so the description thereof is herein omitted.

While the turning on/off of the second additional transistor T2, which is provided on the first differential transistor P1 side, is controlled by the test signal, the turning on/off of the second additional transistor T2a, which is provided on the second differential transistor P2 side, is controlled by the test signal (a). Accordingly, the size balance between the first differential transistor P1 and the second differential transistor P2 can be changed by making one of the test signals active. Note that the two second additional transistors T2 and T2a may be connected to one of the test signals to change the size balance between the offset adding units 20 and 20a which are connected to the first differential transistor P1 and the second differential transistor P2, respectively.

In the operational amplifier according to the second exemplary embodiment, the size balance between the paired transistors, which constitute the differential pair of the operational amplifier, is changed by the offset adding unit. Accordingly, the logic operation of the offset cancel operation can be checked regardless of the actual offset voltage amount of the paired transistors. A discrimination between a defective product incapable of performing the offset cancel function and a product having a small offset amount of the amplifier output under measurement conditions at the time of checking the offset cancel operation, which has been conventionally difficult, can be achieved. Therefore, the offset cancel operation can be determined with higher accuracy.

In the first and second exemplary embodiments, the description has been made of the example where the paired transistors (first differential transistor and second differential transistor), which constitute the input differential stage 10, and the first additional transistor T1 are composed of p-type MOS transistors, and the second additional transistor T2, the current mirror circuit 30, and the switching transistors are composed of n-type MOS transistors. However, the present invention is not limited thereto, and various modifications can be made without departing from the scope of the present invention. For example, the paired transistors (first differential transistor and second differential transistor), which constitute the input differential stage 10, and the first additional transistor T1 may be composed of n-type MOS transistors, and the second additional transistor T2 and the current mirror circuit 30 may be composed of p-type MOS transistors.

Further, in the first exemplary embodiment, the description has been made of the example where the offset adding unit 20 is connected to the first differential transistor P1. However, the connection destination of the offset adding unit 20 is not limited thereto as long as the offset adding unit 20 is connected to as to change the size balance between the first differential transistor P1 and the second differential transistor P2. Accordingly, the offset adding unit 20 may be connected to the second differential transistor P2 instead of the first differential transistor P1.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

The first and second exemplary embodiments can be combined as desirable by one of ordinary skill in the art.

What is claimed is:

1. An operational amplifier comprising:
a differential stage including a first differential transistor and a second differential transistor, the first differential transistor and the second differential transistor serving as paired transistors;
a first polarity switching unit that switches a connection destination of a control terminal of the first differential transistor between an inverting terminal and a non-inverting terminal;
a second polarity switching unit that switches a connection destination of a control terminal of the second differential transistor between the inverting terminal and the non-inverting terminal; and
an offset adding unit that is connected to one or both of the paired transistors to change a size balance between the first differential transistor and the second differential transistor,
wherein the offset adding unit comprises:
a first additional transistor that is connected in parallel with one or both of the paired transistors and receives the same input as one or both of the paired transistors connected; and
a second additional transistor connected in series with the first additional transistor, turning on/off of the second additional transistor being controlled by a test signal.

2. The operational amplifier according to claim 1, wherein
the paired transistors and the first additional transistor are MOS transistors of a first conductivity type, and
the second additional transistor is a MOS transistor of a second conductivity type.

3. The operational amplifier according to claim 1, further comprising:
a current mirror circuit that is connected to the differential stage and serves as an active load unit;
an output unit connected to a node between the differential stage and the current mirror circuit;
a third polarity switching unit that switches a connection destination of each of gates of transistors constituting the current mirror circuit; and
a fourth polarity switching unit that switches a connection destination of the output unit between the first differential transistor and the second differential transistor.

4. The operational amplifier according to claim 2, further comprising:
a current mirror circuit that is connected to the differential stage and serves as an active load unit;
an output unit connected to a node between the differential stage and the current mirror circuit;
a third polarity switching unit that switches a connection destination of each of gates of transistors constituting the current mirror circuit; and
a fourth polarity switching unit that switches a connection destination of the output unit between the first differential transistor and the second differential transistor.

5. A semiconductor device comprising an operational amplifier, wherein
the operational amplifier comprises:
a differential stage including a first differential transistor and a second differential transistor, the first differential transistor and the second differential transistor serving as paired transistors;
a first polarity switching unit that switches a connection destination of a control terminal of the first differential transistor between an inverting terminal and a non-inverting terminal;
a second polarity switching unit that switches a connection destination of a control terminal of the second differential transistor between the inverting terminal and the non-inverting terminal; and
an offset adding unit that is connected to one or both of the paired transistors to change a size balance between the first differential transistor and the second differential transistor, and
the offset adding unit comprises:
a first additional transistor that is connected in parallel with one or both of the paired transistors and receives the same input as one or both of the paired transistors connected; and
a second additional transistor connected in series with the first additional transistor, turning on/off of the second additional transistor being controlled by a test signal.

6. The semiconductor device according to claim 5, wherein
the paired transistors and the first additional transistor are MOS transistors of a first conductivity type, and
the second additional transistor is a MOS transistor of a second conductivity type.

7. The semiconductor device according to claim 5, further comprising:
a current mirror circuit that is connected to the differential stage and serves as an active load unit;
an output unit connected to a node between the differential stage and the current mirror circuit;
a third polarity switching unit that switches a connection destination of each of gates of transistors constituting the current mirror circuit; and
a fourth polarity switching unit that switches a connection destination of the output unit between the first differential transistor and the second differential transistor.

8. The semiconductor device according to claim 6, further comprising:
a current mirror circuit that is connected to the differential stage and serves as an active load unit;
an output unit connected to a node between the differential stage and the current mirror circuit;
a third polarity switching unit that switches a connection destination of each of gates of transistors constituting the current mirror circuit; and
a fourth polarity switching unit that switches a connection destination of the output unit between the first differential transistor and the second differential transistor.

9. A display device comprising a semiconductor device as claimed in claim 5.

10. A display device comprising a semiconductor device as claimed in claim 6.
